(19) United States
(12) Patent Application Publication
(10) Pub. No.: US 2021/0149003 A1
(43) Pub. Date: May 20, 2021

(54) ACTIVE SHIM KNEE COIL

(71) Applicant: Siemens Healthcare GmbH, Erlangen (DE)

(72) Inventors: Ying Lun Wang, Shenzhen (CN); Yan Li Chen, Shenzhen (CN); Zhen Hua Yue, Shenzhen (CN); Wuyi Zhao, Shenzhen (CN)

(73) Assignee: Siemens Healthcare GmbH, Erlangen (DE)

(21) Appl. No.: 17/096,097

(22) Filed: Nov. 12, 2020

(30) Foreign Application Priority Data
Nov. 14, 2019 (CN) 201911112009.0

(51) Int. Cl. G01R 33/3875; G01R 33/54; G01R 33/56

(52) U.S. Cl. CPC G01R 33/3875; G01R 33/5608; G01R 33/543

(57) ABSTRACT

A local shimming device and a method for compensation of non-uniformity of a main magnetic field are disclosed, wherein the local shimming device comprises: a local coil, arranged to cover a local region of an examination subject, to receive a magnetic resonance signal from the local region; multiple shim coils, wherein the multiple shim coils are integrated in the local coil or arranged to surround at least a part of the local coil; and a shimming controller, configured to control at least one shim coil of the multiple shim coils, according to a strength distribution of a main magnetic field in the local region, to provide a field distribution for compensating a component of the main magnetic field in the local region.

### CROSS-REFERENCE TO RELATED APPLICATIONS

The present application claims the benefit of the filing date of China patent application no CN 201911112009.0, filed on Nov. 14, 2019, the contents of which are incorporated herein by reference in their entirety.

### TECHNICAL FIELD

The present disclosure relates to a local shimming device and a method for compensation of non-uniformity of a main magnetic field.

### BACKGROUND

Medical imaging is a technique for obtaining an internal tissue image of the human body or a region of the human body non-invasively for the purpose of medical treatment or medical research and an associated processing procedure, and has become a widely-used important medical diagnosis technique for all regions of the human body. A magnetic resonance imaging (MRI) system using medical imaging technology applies a magnetic field in a cylindrical measurement space accommodating a patient in a basic magnetic field to obtain a magnetic resonance slice photograph in an internal region of the patient's body. That is, image data is generated by means of magnetic resonance technology, and the patient's body is typically exposed to a static main magnetic field that is as uniform as possible. Nuclear spins in the patient's body are thereby aligned parallel to the direction of the basic magnetic field. In addition, a high-frequency pulse is radiated into the patient's body by means of a suitable high-frequency antenna in the region where the patient is positioned, to excite nuclear spins in the patient and thereby excite the transmission of a magnetic resonance signal through the application of a high-frequency field.

The quality of the MRI image to be acquired depends mainly on the uniformity of the main magnetic field, and the uniformity of the main magnetic field is in particular used for fat suppression. In a fat saturation sequence, there are two types of RF pulses, of which one type is used for water signal imaging, and the other is a fat saturation pulse used to suppress a fat signal. The two resonant frequencies of water and fat are quite close to each other. Therefore, if the main magnetic field is not uniform, the resonant frequencies of water and fat become blurred, and it is difficult for the fat saturation pulse to suppress the fat signal.

Conventionally, one solution is to integrate a shim coil in a gradient coil, and to subject the global main magnetic field to compensation by means of a shim current flowing through the shim coil. This improves the uniformity of the main magnetic field such that the main magnetic field through the examination subject or the entire body of the patient is more uniform. However, this solution is extremely complex and costly, and is still unable to effectively solve the problem of non-uniformity of the main magnetic field in local regions of the examination subject. As another solution, high-order magnetic field non-uniformity is corrected during an imaging sequence and/or imaging signal data acquisition by controlling currents flowing through two or more portions of a gradient coil. However, although this solution avoids the use of a shim coil, it is necessary to independently control the currents flowing through different portions of the gradient coil, and this increases operating complexity.

### SUMMARY

In the case of regions with complex anatomical structures, e.g. the irregular structure of the kneecap region, an irregular interface is formed between tissue and air, causing a sharp change in the field distribution of the main magnetic field, with distortion of the main magnetic field close to the kneecap.

To address this issue, the present disclosure thus provides a local shimming device and a method for compensation of non-uniformity of a main magnetic field. The local shimming device according to the aspects of the present disclosure is structurally simple and low in cost, and is able to increase the uniformity of a main magnetic field in a local region of an examination subject, effectively solving the problem of magnetic field distortion in the local region and the resulting fat saturation, and in turn increasing the imaging quality in the local region.

One aspect of the present disclosure provides a local shimming device, comprising: a local coil, arranged to cover a local region of an examination subject to receive a magnetic resonance signal from the local region; multiple shim coils integrated in the local coil or arranged to surround at least a part of the local coil; and a shimming controller configured to control at least one shim coil of the multiple shim coils according to a strength distribution of a main magnetic field in the local region to provide a field distribution for compensating a component of the main magnetic field in the local region. The local shimming device of the present disclosure provides a good shimming result, being capable of effectively eliminating or at least reducing non-uniformity in the main magnetic field distribution in a local region of the examination subject caused by the formation of an irregular interface between tissue and air due to the irregular shape of the region of be examined.

According to an exemplary embodiment of the local shimming device of the present disclosure, in the case where the multiple shim coils are arranged to surround at least a part of the local coil, the local shimming device comprises a sleeve surrounding the local coil, wherein the multiple shim coils are arranged on the sleeve. Thus, the shim coils of the local shimming device can be arranged outside the local coil, closely surrounding at least a part of the local coil, making the structure of the local shimming device compact.

According to an exemplary embodiment of the local shimming device of the present disclosure, the multiple shim coils comprise multiple solenoid-shaped first shim coils and multiple saddle-shaped second shim coils, wherein the first shim coils and the second shim coils are stacked in layers on a tube wall of the sleeve. Shim coils of different shapes outside the local coil offer the possibility of generating different orders of magnetic field components.

According to an exemplary embodiment of the local shimming device of the present disclosure, the first shim coils are configured to generate 2 orders of magnetic field components, and the second shim coils are configured to generate 3 orders or more of magnetic field components. Thus, different parts of the multiple shim coils can work independently to generate different orders of magnetic field components.

According to an exemplary embodiment of the local shimming device of the present disclosure, the local shimming device further comprises: a main magnetic field detector configured to acquire a strength distribution of the main magnetic field in the local region of the examination subject. The magnetic resonance apparatus of the present disclosure provides a good shimming result, being capable of effectively eliminating main magnetic field distortion arising close to a local region of the examination subject and effectively solving the resulting fat saturation problem.

According to an exemplary embodiment of the local shimming device of the present disclosure, the main magnetic field detector is further configured to: collect data relating to the strength distribution of the main magnetic field of the local region by scanning the local region of multiple different examination subjects. Collecting the strength distribution of the main magnetic field in the local region helps to increase the precision of compensation of the main magnetic field in the local region.

According to an exemplary embodiment of the local shimming device of the present disclosure, the shimming controller is further configured to: extract multiple orders of harmonic components of the main magnetic field from the acquired strength distribution of the main magnetic field; and calculate a field distribution to be generated by at least one shim coil of the multiple shim coils such that the field distribution generated by the at least one shim coil can offset at least one order of harmonic component of the multiple orders of harmonic components of the main magnetic field. Using the collected main magnetic field data in the local region, the field strength distribution of the main magnetic field is resolved into multiple orders of harmonic components to facilitate precise compensation of the distorted main magnetic field.

According to an exemplary embodiment of the local shimming device of the present disclosure, the shimming controller is further configured to: use a spherical harmonic to extract the multiple orders of harmonic components of the main magnetic field. Thus, multiple orders of harmonic components of the distorted main magnetic field are represented mathematically, facilitating precise compensation of the main magnetic field in a targeted manner.

According to an exemplary embodiment of the local shimming device of the present disclosure, the local coil is a knee coil. The knee coil can provide a shimming effect for the patella region, thereby solving the problem of non-uniformity of the main magnetic field close to the patella.

Another aspect of the present disclosure provides a method for compensation of non-uniformity of a main magnetic field by means of the local shimming device described above, the method comprising: receiving a magnetic resonance signal from a local region of an examination subject by means of a local coil; determining a field distribution to be generated by at least one shim coil of multiple shim coils by means of a shimming controller according to a strength distribution of a main magnetic field in the local region, wherein the multiple shim coils are integrated in the local coil or arranged to surround at least a part of the local coil; and controlling at least one shim coil of the multiple shim coils by means of the shimming controller to provide a field distribution for compensating a component of the main magnetic field in the local region.

According to an exemplary embodiment of the method for compensation of non-uniformity of a main magnetic field of the present disclosure, receiving a magnetic resonance signal from the local region of the examination subject comprises: collecting data relating to the strength distribution of the main magnetic field of the local region by scanning the local region of multiple different examination subjects.

According to an exemplary embodiment of the method for compensation of non-uniformity of a main magnetic field of the present disclosure, determining a field distribution to be generated by at least one shim coil of the multiple shim coils comprises: extracting multiple orders of harmonic components of the main magnetic field from an acquired strength distribution of the main magnetic field; and calculating a field distribution to be generated by at least one shim coil of the multiple shim coils such that the field distribution generated by the at least one shim coil can offset at least one order of harmonic component of the multiple orders of harmonic components of the main magnetic field.

According to an exemplary embodiment of the method for compensation of non-uniformity of a main magnetic field of the present disclosure, extracting multiple orders of harmonic components of the main magnetic field comprises: using a spherical harmonic to extract the multiple orders of harmonic components of the main magnetic field.

According to another aspect of the present disclosure, the present disclosure provides a storage medium (e.g. a non-transitory computer-readable medium), comprising a stored program, wherein when the program is executed, a device in which the storage medium is located is controlled to execute the method as described above.

According to another aspect of the present disclosure, the present disclosure provides a processor for executing a program, wherein the method as described above is executed when the program is executed.

### BRIEF DESCRIPTION OF THE DRAWINGS/FIGURES

The accompanying drawings form a part of this Description, and are intended to be of assistance in gaining further understanding of the present disclosure. These drawings illustrate embodiments of the present disclosure, and together with the Description are intended to explain the principles of the present disclosure. In the drawings, identical components are indicated using identical labels. The following are shown in the drawings:

FIG. 1 shows a structural schematic diagram of an example local shimming device according to one or more embodiments of the present disclosure.

FIG. 2 shows a schematic diagram of an example local coil with shim coils mounted thereon according to one or more embodiments of the present disclosure.

FIG. 3 shows a schematic flow chart of an example method for compensation of non-uniformity of a main magnetic field according to one or more embodiments of the present disclosure.

FIG. 4 shows a schematic flow chart of an example method for compensation of non-uniformity of a main magnetic field according to one or more embodiments of the present disclosure.

Key to labels used in the drawings:

11: local coil;

13: shim coil;

15: shimming controller;

17: main magnetic field detector;

20: sleeve;

100: local shimming device.

### DETAILED DESCRIPTION

To enable those skilled in the art to better understand the solution of the present disclosure, the technical solution in the embodiments of the present disclosure is described clearly and completely below in conjunction with the drawings in the embodiments of the present disclosure. Obviously, the embodiments described are only some, not all, of the embodiments of the present disclosure. All other solutions obtained by those skilled in the art on the basis of embodiments of the present disclosure without any creative effort should fall within the scope of protection of the present disclosure.

It is explained that the terms “comprise” and “have” and any variants thereof in the description and claims of the present disclosure and the abovementioned drawings are intended to cover non-exclusive inclusion. For example, products or devices comprising a series of units are not necessarily limited to those units which are clearly listed, but may comprise other units which are not listed or are intrinsic to these products or devices.

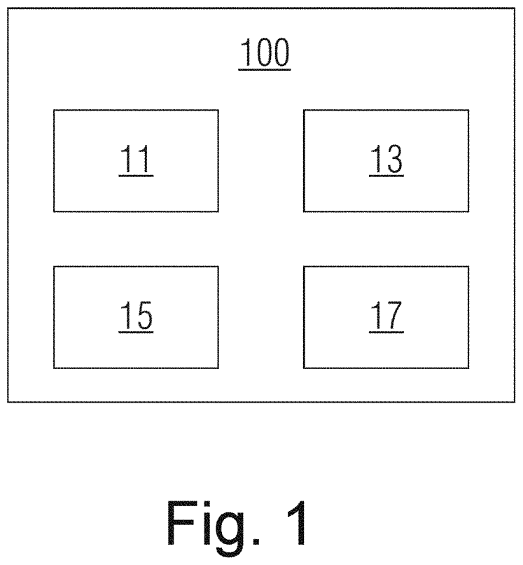

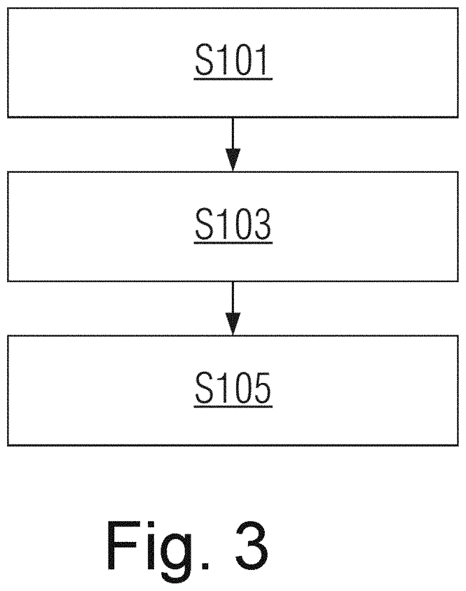

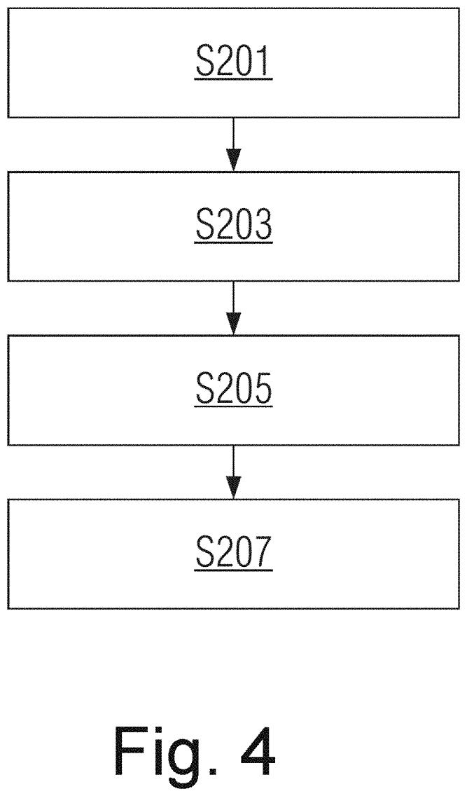

FIG. 1 shows a structural schematic diagram of an example local shimming device according to one or more embodiments of the present disclosure. In the embodiment of the present disclosure, as shown in FIG. 1, the local shimming device 100 comprises a local coil 11, multiple shim coils 13, and a shimming controller 15. The local coil 11 is arranged to cover a local region of an examination subject to receive a magnetic resonance signal from the local region. The multiple shim coils 13 may be integrated in the local coil 11 or arranged to surround at least a part of the local coil 11. The shimming controller 15 is configured to control at least one shim coil of the multiple shim coils 13 according to a strength distribution of a main magnetic field in the local region to provide a field distribution for compensating a component of the main magnetic field in the local region. The shimming controller 15 may include or otherwise access a storage medium (e.g. a non-transitory computer-readable storage medium), which may store executable instructions. The instructions may, when executed by the shimming controller 15, execute the methods and techniques as discussed herein, such as those as shown and described with reference to FIGS. 3 and 4, for example.

The shimming controller 15 is further configured to extract multiple orders of harmonic components of the main magnetic field from an acquired strength distribution of the main magnetic field. For example, the characteristics of the main magnetic field close to the kneecap (patella) of the examination subject or patient are described mathematically: spherical harmonics may be used, for example, as a basis to extract different harmonic components of the main magnetic field, i.e. first-order, second-order, third-order, and higher-order harmonic components, preferably to extract five orders of harmonic components, i.e. the first-order to fifth-order harmonic components of the main magnetic field, to characterize the main magnetic field close to the kneecap. The main magnetic field may be reconstructed in a spherical region by means of the extracted five orders of harmonic components.

The shimming controller 15 is further configured to calculate a field distribution to be generated by at least one shim coil of the multiple shim coils 13 such that the field distribution generated by the at least one shim coil can offset at least one order of harmonic component of the multiple orders of harmonic components of the main magnetic field. A magnetic field harmonic component generated by one or more shim coils of the multiple shim coils 13 has the same amplitude, but is in the opposite direction, of each corresponding harmonic component of the main magnetic field in the kneecap local region, and thereby offsets the distorted main magnetic field. For example, each shim coil of the multiple shim coils 13 is designed to be able to generate a magnetic field harmonic component meeting requirements, i.e. each shim coil of the multiple shim coils 13 can generate at least one or more of five orders of harmonic components. For example, one shim coil of the multiple shim coils 13 may be designed to generate a first-order harmonic component and a second-order harmonic component. The number of shim coils used for shimming can thereby be reduced. The direction of the magnetic field harmonic component generated by the shim coil of the multiple shim coils 13 is opposite to the direction of the harmonic component extracted from the main magnetic field close to the patient's kneecap.

Furthermore, for different situations, first-order, second-order, or higher-order shim coils of the multiple shim coils 13 may be correspondingly used. For example, if it is necessary to generate linear compensation of the main magnetic field, it is possible to just use a shim coil of the multiple shim coils 13 for generating a first-order harmonic component magnetic field. In the case of this first-order shim coil, by creating a compensating magnetic field that has the same amplitude as, but the opposite symbol (opposite direction) to, the first-order harmonic component of the main magnetic field, magnetic field distortion in the X, Y, and Z directions can be eliminated to retain a uniform main magnetic field. For example, to eliminate a distorted main magnetic field close to the patient's kneecap, it may be necessary to use a second-order or higher-order shim coil of the multiple shim coils 13. For example, in the case of the second-order shim coil of the multiple shim coils 13, by creating a compensating magnetic field that has the same amplitude as, but the opposite symbol (e.g. opposite direction) to the second-order harmonic component of the main magnetic field, main magnetic field distortion in the XY, ZX, XY, Z2, and X2-Y2 directions can be eliminated to retain a uniform main magnetic field.

The local shimming device 100 further comprises a main magnetic field detector 17 configured to acquire a strength distribution of the main magnetic field in a local region of an examination subject. The main magnetic field detector 17 is further configured to collect data relating to the strength distribution of the main magnetic field in the local region by scanning the local region of one or more examination subjects. In one embodiment, the main magnetic field close to the kneecap (patella) of one patient is scanned to acquire original data of a nearby main magnetic field strength distribution, which can be processed by software (e.g. MATLAB) to obtain a magnetic field strength distribution of a scanned region. In another embodiment, initial data of the main magnetic field is acquired in advance in the vicinity of the kneecaps of multiple different patients to create “Big Data” sets of the magnetic field strength distribution corresponding to this region, which may be used for analysis and processing, and the field strength distribution of the main magnetic field is obtained as a basis for subsequent compensation of the main magnetic field. This helps to further improve the precision of compensation.

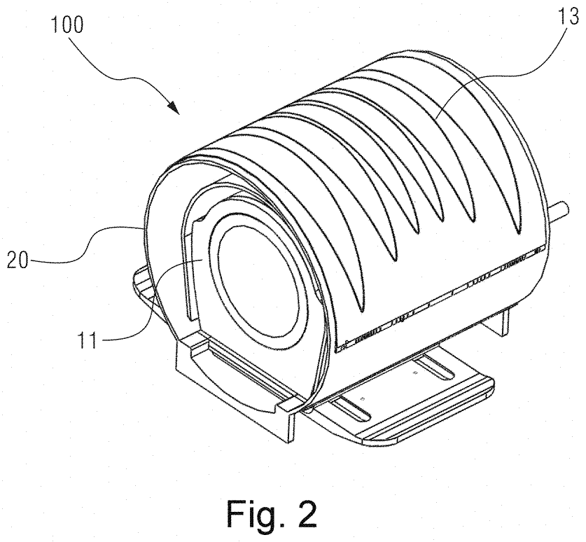

FIG. 2 shows a schematic diagram of an example local coil with shim coils mounted thereon according to one or more embodiments of the present disclosure. As shown in FIG. 2, the local shimming device 100 comprises the local coil 11 and the multiple shim coils 13 mounted on the local coil 11. With regard to the multiple shim coils 13, according to an embodiment of the present disclosure, these shim coils 13 can be disposed outside the local coil 11 or integrated inside the local coil 11. If the shim coils 13 are integrated inside the local coil 11, the coil dimensions will not be increased, and costs can be reduced. Alternatively, if the internal space of the local coil 11 is sufficient, an additional holder (e.g. a round sleeve 20) may be disposed outside the local coil 11 for the purpose of assembling the multiple shim coils 13, wherein the round sleeve 20 surrounds the local coil 11 as closely as possible to obtain a good local shimming effect. For example, to examine an examination subject's knee, multiple shim coils 13 may be integrated in a knee coil or a sleeve 20 that closely surrounds the knee coil may be designed, with multiple shim coils 13 distributed on the sleeve.

As shown in FIG. 2, the round sleeve 20 that is designed may be used in cooperation with an existing knee coil to provide fixing of the knee coil. The multiple shim coils 13 are distributed on the round sleeve 20 surrounding the local coil 11 and comprise multiple solenoid-shaped shim coils and multiple saddle-shaped shim coils; the multiple shim coils 13 of these two shapes are stacked in layers on a tube wall of the round sleeve 20. For example, the multiple solenoid-shaped shim coils may generate 2 orders of magnetic field components, and the multiple saddle-shaped shim coils may generate 3 orders or more of magnetic field components. The round sleeve 20 is equipped with a control and power supply cable so as to provide a shimming current to the multiple shim coils 13 on the round sleeve 20.

FIG. 3 shows a schematic flow chart of an example method for compensation of non-uniformity of a main magnetic field according to one or more embodiments of the present disclosure. The method according to an embodiment of the present disclosure comprises:

Step S101, receiving a magnetic resonance signal from a local region of an examination subject by means of a local coil. For example, by scanning a main magnetic field close to a patient's kneecap, original data of a main magnetic field strength distribution close to the kneecap is acquired.

Step S103, determining a field distribution to be generated by at least one of multiple shim coils integrated in the local coil or arranged to surround at least a part of the local coil, by means of a shimming controller according to a strength distribution of a main magnetic field in the local region. By analyzing the acquired data of the main magnetic field strength distribution close to the patient's kneecap, it is possible to calculate the field distribution that should be generated for one or more or each of the multiple shim coils.

Step S105, controlling at least one of the multiple shim coils by means of the shimming controller to provide a field distribution for compensating a component of the main magnetic field in the local region. The direction of the field distribution generated by one or more of the multiple shim coils is opposite to the direction of the main magnetic field in the kneecap local region for the purpose of offsetting the distorted main magnetic field.

FIG. 4 shows a schematic flow chart of an example method for compensation of non-uniformity of a main magnetic field according to one or more embodiments of the present disclosure. In this exemplary embodiment, the method of the present disclosure comprises:

Step S201, collecting data relating to a strength distribution of a main magnetic field of a local region by scanning the local region of multiple different examination subjects. For example, initial data of the main magnetic field may be acquired in advance from the vicinity of the kneecaps of multiple different patients to create Big Data sets of the magnetic field strength distribution corresponding to this region, to be used for analysis and processing, and the field strength distribution of the main magnetic field is obtained as a basis for subsequent compensation of the main magnetic field. This helps to further improve the precision of compensation.

Step S203, using spherical harmonics to extract multiple orders of harmonic components of the main magnetic field from an acquired strength distribution of the main magnetic field. In order to mathematically describe the characteristics of the main magnetic field close to the patient's kneecap, for example, spherical harmonics are used as a basis to extract different harmonic components of the main magnetic field, i.e. first-order, second-order, third-order, and higher-order harmonic components, preferably to extract five orders of harmonic components, i.e. the first-order to fifth-order harmonic components of the main magnetic field to characterize the main magnetic field close to the kneecap. The main magnetic field is reconstructed in a spherical region by means of the extracted five orders of harmonic components.

Step S205, calculating a field distribution to be generated by at least one of multiple shim coils such that the field distribution generated by the at least one shim coil can offset at least one order of harmonic component of the multiple orders of harmonic components of the main magnetic field. The multiple shim coils are integrated in a local coil or arranged to surround at least a part of the local coil. For example, one of the multiple shim coils may be designed to generate a first-order harmonic component and a second-order harmonic component. The direction of the magnetic field harmonic component generated by the shim coil is opposite to the direction of the harmonic component extracted from the main magnetic field close to the patient's kneecap.

Step S207, controlling at least one of the multiple shim coils by means of a shimming controller to provide a field distribution for compensating a component of the main magnetic field in the local region. The shimming controller controls a shimming current provided to at least one shim coil. For example, if it is necessary to generate linear compensation of the main magnetic field, it is possible to just use a shim coil for generating a first-order harmonic component magnetic field. For example, to eliminate a distorted main magnetic field close to the patient's kneecap, it may be necessary to use a second-order or higher-order shim coil.

It should be understood that the technical content disclosed in the embodiments provided by the present disclosure can be realized in other ways. The above-described embodiments of the device are by way of example and not limitation. For example, the division of units or modules is merely a logic function division, and other manners of division are possible in actual implementation. For example, multiple units or modules or components can be combined or integrated into another system, some characteristics can be omitted or not executed. In addition, any shown or discussed couplings or direct couplings may be indirect couplings, electrical or otherwise, via some interfaces, modules, or units.

The above are merely example embodiments of the present disclosure, which are not intended to limit it. To those skilled in the art, various modifications and changes to the present disclosure are possible. Any amendments, equivalent substitutions or improvements etc. made within the spirit and principles of the present disclosure shall be included in the scope of protection thereof.

What is claimed is:

1. A shimming device, comprising:
a local coil arranged to cover a region of an examination subject to receive a magnetic resonance signal from the region;
multiple shim coils integrated in the local coil or arranged to surround at least a part of the local coil; and
a shimming controller configured to control at least one shim coil of the multiple shim coils according to a strength distribution of a main magnetic field present in the region of the examination subject to provide a field distribution that compensates for at least one component of the main magnetic field to reduce non-uniformity in the main magnetic field caused by an interface formed between tissue and air at the region of the examination subject.

2. The shimming device as claimed in claim 1, wherein:
the multiple shim coils are arranged to surround at least a part of the local coil,
the shimming device further comprises a sleeve surrounding the local coil, and
the multiple shim coils are arranged on the sleeve.

3. The shimming device as claimed in claim 2, wherein the multiple shim coils comprise multiple solenoid-shaped first shim coils and multiple saddle-shaped second shim coils, and
wherein the first shim coils and the second shim coils are stacked in layers on a tube wall of the sleeve.

4. The shimming device as claimed in claim 3, wherein the first shim coils are configured to generate 2 orders of magnetic field components, and
wherein the second shim coils are configured to generate at least 3 orders of magnetic field components.

5. The shimming device as claimed in claim 1, further comprising:
a main magnetic field detector configured to acquire the strength distribution of the main magnetic field in the region of the examination subject.

6. The shimming device as claimed in claim 5, wherein the main magnetic field detector is further configured to collect data associated with the strength distribution of the main magnetic field of the region of the examination subject by scanning a local region of multiple different examination subjects.

7. The shimming device as claimed in claim 6, wherein the shimming controller is further configured to:
extract multiple orders of harmonic components of the main magnetic field from the acquired strength distribution of the main magnetic field; and
calculate a field distribution to be generated by at least one shim coil of the multiple shim coils such that the field distribution generated by the at least one shim coil offsets at least one order of a harmonic component of the multiple orders of harmonic components of the main magnetic field.

8. The shimming device as claimed in claim 7, wherein the shimming controller is further configured to utilize a spherical harmonic to extract the multiple orders of harmonic components of the main magnetic field.

9. The shimming device as claimed in claim 1, wherein the local coil is a knee coil.

10. A method for compensating for non-uniformity of a main magnetic field using a local shimming device, the method comprising:
receiving a magnetic resonance signal from a region of an examination subject via a local coil;
determining a field distribution to be generated by at least one shim coil of multiple shim coils via a shimming controller according to a strength distribution of a main magnetic field in the region, the multiple shim coils being integrated in the local coil or arranged to surround at least a part of the local coil; and
controlling at least one shim coil of the multiple shim coils using the shimming controller to provide a field distribution that compensates for at least one component of the main magnetic field in the local region to reduce non-uniformity in the main magnetic field caused by an interface formed between tissue and air at the region of the examination subject.

11. The method as claimed in claim 10, wherein the act of receiving the magnetic resonance signal from the region of the examination subject comprises:
collecting data associated with the strength distribution of the main magnetic field of the region of the examination subject by scanning a local region of multiple different examination subjects.

12. The method as claimed in claim 10, wherein the act of determining a field distribution to be generated by at least one shim coil of the multiple shim coils (13) comprises:
extracting multiple orders of harmonic components of the main magnetic field from the acquired strength distribution of the main magnetic field; and
calculating a field distribution to be generated by at least one shim coil of the multiple shim coils such that the field distribution generated by the at least one shim coil offsets at least one order of a harmonic component of the multiple orders of harmonic components of the main magnetic field.

13. The method as claimed in claim 12, wherein the act of extracting multiple orders of harmonic components of the main magnetic field comprises:
using a spherical harmonic to extract the multiple orders of harmonic components of the main magnetic field.

14. A non-transitory computer readable medium associated with a shimming device, the transitory computer readable medium having instructions stored thereon that, when executed by a shimming controller of the shimming device, cause the shimming device to compensate for non-uniformity of a main magnetic field by:
receiving a magnetic resonance signal from a region of an examination subject via a local coil;
determining a field distribution to be generated by at least one shim coil of multiple shim coils according to a strength distribution of a main magnetic field in the region, the multiple shim coils being integrated in the local coil or arranged to surround at least a part of the local coil; and
controlling at least one shim coil of the multiple shim coils to provide a field distribution that compensates for at least one component of the main magnetic field in the local region to reduce non-uniformity in the main magnetic field caused by an interface formed between tissue and air at the region of the examination subject.
